(19) United States
(12) Patent Application Publication
(10) Pub. No.: US 2015/0221385 A1
(43) Pub. Date: Aug. 6, 2015

(54) SEMICONDUCTOR MEMORY DEVICE AND SYSTEM INCLUDING THE SAME

(71) Applicant: SK hynix Inc., Gyeonggi-do (KR)

(72) Inventors: Sang Tae AHN, Seoul (KR); Gyu Seog CHO, Gyeonggi-do (KR)

(21) Appl. No.: 14/333,243

(22) Filed: Jul. 16, 2014

(30) Foreign Application Priority Data
Feb. 4, 2014 (KR) 10-2014-0012682

(51) Int. Cl. G11C 16/28; G11C 16/04; G11C 16/14

(52) U.S. Cl. CPC G11C 16/28; G11C 16/14; G11C 16/0483

(57) ABSTRACT

A semiconductor memory device includes a plurality of normal memory cells stacked over a substrate and coupled in series with each other, a plurality of selection transistors coupled in series, and one or more dummy memory cells coupled between the plurality of normal memory cells and the plurality of selection transistors, wherein the plurality of selection transistors includes first and second selection transistors, and the first selection transistor is adjacent to the dummy memory cells, and has a lower threshold voltage than the second selection transistor.

### CROSS-REFERENCE TO RELATED APPLICATION

The present application claims priority to Korean patent application number 10-2014-0012682, filed on Feb. 4, 2014, the entire disclosure of which is incorporated herein in its entirety by reference.

### BACKGROUND

1. Field of Invention

Various exemplary embodiments of the present invention relate generally to an electronic device, and more particularly, to a semiconductor memory device and a system including the same.

2. Description of Related Art

Semiconductor memory devices are embodied with semiconductors such as silicon (Si), germanium (Ge), gallium arsenide (GaAs), or indium phosphide (Inp). Semiconductor memory devices are classified into volatile memory devices and non-volatile memory devices.

Volatile memory devices lose stored data when the power is off. Examples of volatile memory devices include Static RAM (SRAM), Dynamic RAM (DRAM) and Synchronous DRAM (SDRAM). Non-volatile memory devices can retain stored data regardless of power on/off conditions. Examples of non-volatile memory include Read Only Memory (ROM), Mask ROM (MROM), Programmable ROM (PROM), Erasable Programmable ROM (EPROM), Electrically Erasable and Programmable ROM (EEPROM), flash memory, Phase-change Random Access Memory (PRAM), Magnetic RAM (MRAM), Resistive RAM (RRAM) and Ferroelectric RAM (FRAM). Flash memories may be classified into NOR-type memories and NAND-type memories.

Recently, to improve the degree of integration in semiconductor memory devices, research has been conducted on semiconductor memory devices having a three-dimensional array structure.

### SUMMARY

Exemplary embodiments of the present invention are directed to improving reliability of program operations in semiconductor memory devices including a three-dimensional memory cell array.

A semiconductor memory device according to an embodiment of the present invention may include a plurality of normal memory cells stacked over a substrate and coupled in series with each other, a plurality of selection transistors coupled in series, and one or more dummy memory cells coupled between the plurality of normal memory cells and the plurality of selection transistors, wherein the plurality of selection transistors include first and second selection transistors, and the first selection transistor is adjacent to the dummy memory cells, and has a lower threshold voltage than the second selection transistor.

The threshold voltage of the first selection transistor may be lower than a ground voltage, and the second selection transistor may have a higher voltage than the ground voltage.

The threshold voltage of the first selection transistor may correspond to an erase state.

A single voltage may be applied to the plurality of selection transistors during a program operation.

A dummy word line voltage lower than voltages applied to the plurality of normal memory cells may be applied to the one or more dummy memory cells during the program operation, and the single voltage applied to the plurality of selection transistors may be lower than the dummy word line voltage.

Dummy word line voltages may be applied to dummy memory cells during a program operation, and the dummy word line voltages decrease as corresponding dummy memory cell is closer to the plurality of selection transistors. A lower voltage than the dummy word line voltages may be applied to the plurality of selection transistors.

A semiconductor memory device according to another embodiment of the present invention may include a plurality of normal memory cells stacked over a substrate and coupled in series, a plurality of selection transistors coupled in series, and one or more dummy memory cells coupled between the plurality of normal memory cells and the plurality of selection transistors, wherein the plurality of selection transistors includes a first selection transistor, and the first selection transistor is adjacent to the dummy memory cells, and has a lower threshold voltage than a ground voltage.

A method of programming the semiconductor memory device according to an embodiment of the present invention may include applying a dummy word line voltage to the dummy memory cells; and applying to the plurality of selection transistors a lower voltage than the dummy word line voltage.

A semiconductor memory device according to yet another embodiment of the present invention may include a plurality of normal memory cell groups stacked over a substrate, one or more dummy memory cell groups formed on the plurality of normal memory cell groups, and a plurality of selection transistor groups sequentially formed on the dummy memory cell groups, wherein the plurality of selection transistor groups include first and second selection transistor groups, and selection transistors of the first selection transistor group are adjacent to the dummy memory cell groups, and have lower threshold voltages than selection transistors of the second selection transistor group.

### BRIEF DESCRIPTION OF THE DRAWINGS

FIG. 1 is a block diagram illustrating a semiconductor memory device;

FIG. 2 is a block diagram illustrating a memory cell array shown in FIG. 1;

FIG. 3 is a circuit diagram illustrating a memory block shown in FIG. 2;

FIG. 4 is a circuit diagram illustrating a memory block shown in FIG. 2;

FIG. 5 is a table showing threshold voltage states of selection transistors according to an embodiment of the present invention;

FIG. 6 is a flowchart illustrating a method of setting selection transistors to have threshold voltage states shown in FIG. 5;

FIG. 7 illustrates voltages applied to selection lines in a program method of a semiconductor memory device according to an embodiment of the present invention;

FIG. 8 is a view Illustrating a potential distribution of a channel layer of a cell string during a program operation shown in FIG. 7;

FIG. 9 is a view illustrating a potential distribution of a channel layer when near selection transistors adjacent to a dummy memory cell have a program state;

FIG. 10 is a view Illustrating a potential distribution of a channel layer when a first drain selection transistor and a third source selection transistor shown in FIG. 8 are replaced by dummy memory cells;

FIG. 11 is a block diagram illustrating a memory system including a semiconductor memory device shown in FIG. 1;

FIG. 12 is a block diagram illustrating an application example of a memory system shown in FIG. 11; and

FIG. 13 is a block diagram illustrating a computing system including a memory system shown in FIG. 12.

### DETAILED DESCRIPTION

Hereinafter, various exemplary embodiments of the present invention will be described in detail with reference to the accompanying drawings. The figures are provided to enable those of ordinary skill in the art to make and use the present invention according to the exemplary embodiments of the present invention.

Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form, and vice versa, as long as it is not specifically.

It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween.

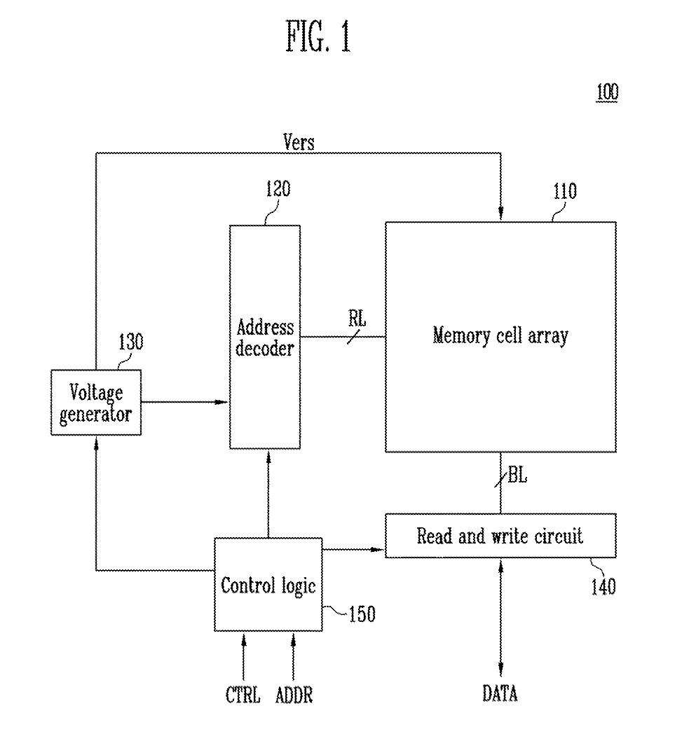

FIG. 1 is a block diagram illustrating a semiconductor memory device 100.

Referring to FIG. 1, the semiconductor memory device 100 may include a memory cell array 110, an address decoder 120, a voltage generator 130, a read and write circuit 140 and a control logic 150.

The memory cell array 110 may be coupled to the address decoder 120 through row lines RL. The memory cell array 110 may be coupled to the read and write circuit 140 through bit lines BL.

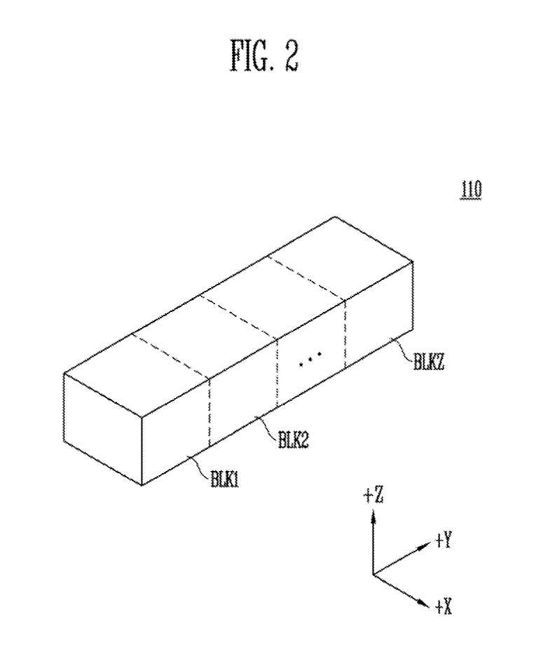

The memory cell array 110 may include a plurality of memory blocks. Each of the memory blocks may include a plurality of cell strings. Each of the cell strings may include a plurality of memory cells stacked over a substrate. According to an embodiment, the plurality of memory cells may be non-volatile memory cells. According to an embodiment, each of the plurality of memory cells may be a single level cell or a multi level cell. The memory cell array 110 will be described below in detail with reference to FIGS. 2 to 4.

The address decoder 120 may be coupled to the memory cell array 110 through the row lines RL. The row lines RL may include drain selection lines, word lines, source selection lines and a common source line. According to an embodiment, the row lines RL may further include a selection line.

The address decoder 120 may drive the row lines RL under control of the control logic 150. The address decoder 120 may receive an address ADDR from the control logic 150.

According to an embodiment, during a program operation and a read operation, the address ADDR may include a block address and a row address. The address decoder 120 may decode the block address in the received address ADDR. The address decoder 120 may select a single memory block according to the decoded block address. The address decoder 120 may decode the row address in the received address ADDR. The address decoder 120 may apply a program voltage provided from the voltage generator 130 to a selected word line of the selected memory block in response to the decoded row address, and apply a pass voltage provided from the voltage generator 130 to unselected word lines of the selected memory block in response to the decoded row address.

According to an embodiment, during an erase operation, the address ADDR may include the block address. The address decoder 120 may decode the block address, and select a single memory block according to the decoded block address when an erase voltage Vers is applied from the voltage generator 130 to the memory cell array 110. For example, when the erase voltage Vers is applied from the voltage generator 130 to the memory cell array 110, the address decoder 120 may apply a ground voltage to word lines coupled to the selected memory block, and float drain selection lines and source selection lines through the row lines RL in order to erase memory cells included in the selected memory block.

According to an embodiment, during the erase operation, the address ADDR may further include the row address. The address decoder 120 may decode the block address and the row address, select a single memory block in response to the decoded block address, and select word lines in the selected memory block in response to the decoded row address when the erase voltage Vers is applied to the memory cell array 110. For example, when the erase voltage Vers is applied from the voltage generator 130 to the memory cell array 110, the address decoder 120 may apply the ground voltage to selected word lines in the selected memory block, and float unselected word lines, drain selection lines and source selection lines in order to erase memory cells electrically coupled to the selected word lines.

The address decoder 120 may include a block decoder, a row decoder and an address buffer.

The voltage generator 130 may generate and apply a plurality of voltages based on an external voltage provided to the semiconductor memory device 100. The voltage generator 130 may be controlled by the control logic 150.

According to an embodiment, the voltage generator 130 may include a circuit regulating the external voltage to generate a power voltage. According to an embodiment, the voltage generator 130 may include a plurality of pumping capacitors receiving the power voltage and generate a plurality of voltages by selecting the plurality of pumping capacitors. The erase voltage Vers among the plurality of voltages may be transferred to the memory cell array 110 and cell strings of the selected memory block. Other voltages of the plurality of voltages may be transferred to the address decoder 120.

The read and write circuit 140 may be coupled to the memory cell array 110 through the bit lines BL. The read and write circuit 140 may operate under control of the control logic 150.

During the erase operation, the read and write circuit 140 may float the bit lines BL. During the program operation and the read operation, the read and write circuit 140 may perform data communication with an input/output buffer (not illustrated) of the semiconductor memory device 100.

According to an embodiment, the read and write circuit 140 may include page buffers (or page registers) and a column selection circuit.

The control logic 150 may be coupled to the address decoder 120, the voltage generator 130 and the read and write circuit 140. The control logic 150 may receive a control signal CTRL and the address ADDR from an external device or an input/output buffer (not illustrated) of the semiconductor memory device 100. The control logic 150 may control general operations of the semiconductor memory device 100 in response to the control signal CTRL. The control logic 150 may provide the address ADDR to the address decoder 120.

The semiconductor memory device 100 may further include an input/output buffer (not illustrated). The input/output buffer may externally receive the control signal CTRL and the address ADDR, and transfer the control signal CTRL and the address ADDR to the control logic 150. In addition, the input/output buffer may transfer the externally received data DATA to the read and write circuit 140, and externally transfer the data DATA from the read and write circuit 140.

According to an embodiment, the semiconductor memory device 100 may be a flash memory device.

FIG. 2 is a block diagram illustrating the memory cell array 110 shown in FIG. 1.

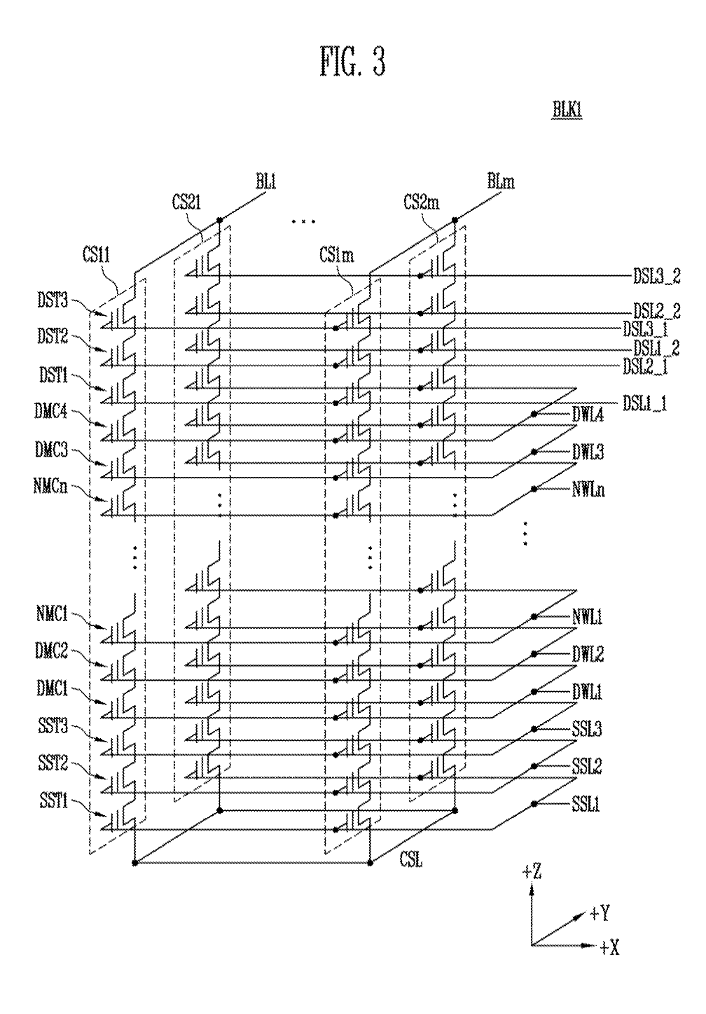

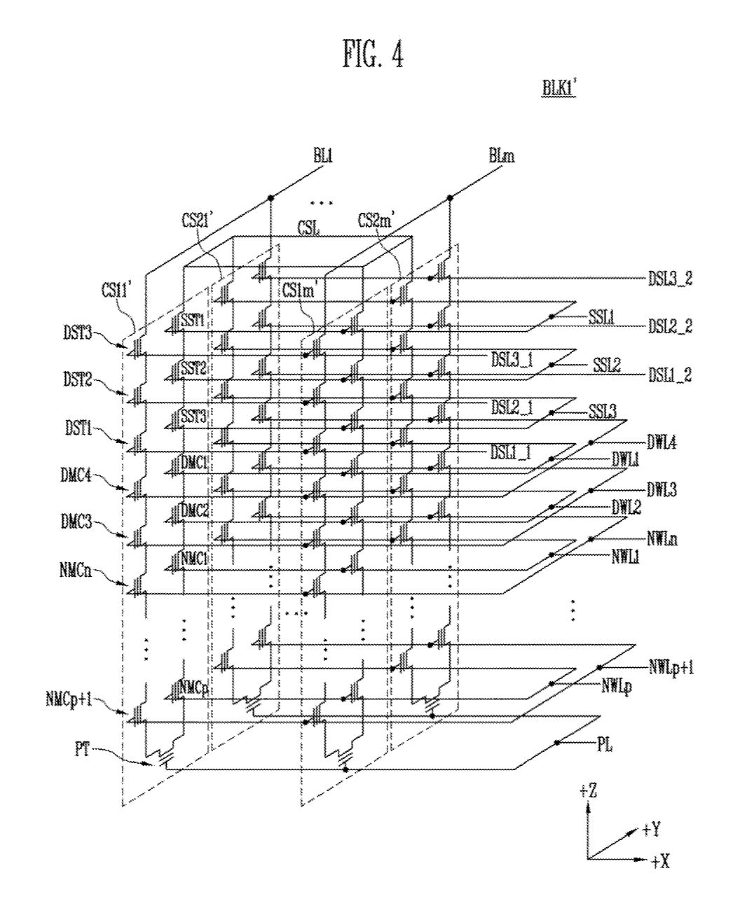

Referring to FIG. 2, the memory cell array 110 may include a plurality of memory blocks BLK1 to BLKz. Each of the memory blocks BLK1 to BLKz may include a plurality of memory cells stacked over the substrate. These memory cells may be arranged in a +X direction, a +Y direction and a +Z direction. The structure of the memory blocks will be described in detail with reference to FIGS. 3 and 4.

FIG. 3 is a circuit diagram illustrating one of the memory blocks BLK1 to BLKz shown in FIG. 2, for example, an embodiment of a first memory block BLK1.

Referring to FIG. 3, the first memory block BLK1 may include a plurality of cell strings CS11 to CS1m and CS21 to CS2m. Each of the cell strings CS11 to CS1m and CS21 to CS2m may extend in the +Z direction. Each of the cell strings CS11 to CS1m and CS21 to CS2m may include first to third source selection transistors SST1 to SST3, first and second dummy memory cells DMC1 and DMC2, first to n-th normal memory cells NMC1 to NMCn, third and fourth dummy memory cells DMC3 and DMC4, and first to third drain selection transistors DST1 to DST3 stacked in the +Z direction. The selection transistors SST1 to SST3 and DST1 to DST3, the dummy memory cells DMC1 to DMC4 and the normal memory cells NMC1 to NMCn may have substantially similar structures to each other. For example, each of the selection transistors SST1 to SST3 and DST1 to DST3, the dummy memory cells DMC1 to DMC4 and the normal memory cells NMC1 to NMCn may include a channel layer, a tunneling insulating layer, a charge storage layer, and a blocking insulating layer coupled to a corresponding row line.

The first to third source selection transistors SST1 to SST3 of each cell string may be coupled in series between the dummy memory cells DMC1 and DMC2 and the common source line CSL. Source selection transistors located at the same height may be coupled to the same source selection line. For example, the first source selection transistors SST1 of the cell strings CS11 to CS1m and CS21 to CS2m may be coupled to the first source selection line SSL1. The second source selection transistor SST2 of the cell strings CS11 to CS1m and CS21 to CS2m may be coupled to the second source selection line SSL2. The third source selection transistors SST3 of the cell strings CS11 to CS1m and CS21 to CS2m may be coupled to the third source selection line SSL3.

The first and second dummy memory cells DMC1 and DMC2 of each cell string may be coupled in series between the normal memory cells NMC1 to NMCn and the source selection transistors SST1 to SST3. Dummy memory cells located at the same height may be coupled to the same dummy word line. For example, the first and second dummy memory cells DMC1 and DMC2 of the cell strings CS11 to CS1m and CS21 to CS2m may be coupled to first and second dummy word lines DWL1 and DWL2, respectively.

The first to n-th normal memory cells NMC1 to NMCn of each cell string may be coupled in series between the first and second dummy memory cells DMC1 and DMC2 and the third and fourth dummy memory cells DMC3 and DMC4. Normal memory cells located at the same height may form a single normal memory cell group and be coupled to the same normal word line. For example, the first to n-th normal memory cells NMC1 to NMCn of the cell strings CS11 to CS1m and CS21 to CS2m may be coupled to first to n-th normal word lines NWL1 to NWLn, respectively.

The third and fourth dummy memory cells DMC3 and DMC4 of each cell string may be coupled in series between the drain selection transistors DST1 to DST3 and the normal memory cells NMC1 to NMCn. For example, the third and fourth dummy memory cells DMC3 and DMC4 may be coupled to the third and fourth dummy word lines DWL3 and DWL4, respectively.

The first to third drain selection transistors DST1 to DST3 of each cell string may be coupled in series between the corresponding bit line and the dummy memory cells DMC3 and DMC4. Drain selection transistors of cell strings located at the same height and in the same row (+X direction) may be coupled to the same drain selection line. Drain selection transistors of cell strings located at the same height in different rows may be coupled to different drain selection lines.

For example, the first drain selection transistor DST1 of each of the cell strings CS11 to CS1m in a first row may be coupled to a first drain selection line DSL1_1. The second drain selection transistor DST2 of each of the cell strings CS11 to CS1m in the first row may be coupled to a second drain selection line DSL2_1. The third drain selection transistor DST3 of each of the cell strings CS11 to CS1m in the first row may be coupled to a third drain selection line DSL3_1. The first drain selection transistor DST1 of each of the cell strings CS21 to CS2m in a second row may be coupled to a first drain selection line DSL1_2. The second drain selection transistor DST2 of each of the cell strings CS21 to CS2m in the second row may be coupled to a second drain selection line DSL2_2. The third drain selection transistor DST3 of each of the cell strings CS21 to CS2m in the second row may be coupled to a third drain selection line DSL3_2.

FIG. 4 is a circuit diagram illustrating one of the memory blocks BLK1 to BLKz shown in FIG. 2, for example, another embodiment of the first memory block BLK1′.

Referring to FIG. 4, the first memory block BLK1′ may include cell strings CS11′ to CS1m′ and CS21′ to CS2m′. For example, each of the cell strings CS11′ to CS1m′ and CS21′ to CS2m′ may be formed into a U shape. Each of the cell strings CS11′ to CS1m′ and CS21′ to CS2m′ may include first to third source selection transistors SST1 to SST3, first to fourth dummy memory cells DMC1 to DMC4, first to n-th normal memory cells NMC1 to NMCn, a pipe transistor PT, and first to third drain selection transistors DST1 to DST3.

The first to third source selection transistors SST1 to SST3 of each cell string may be coupled between the common source line CSL and the first and second dummy memory cells DMC1 and DMC2.

Source selection transistors located at the same height may be coupled to the same source selection line. For example, the first to third source selection transistors SST1 to SST3 of each cell string may be coupled to the first to third source selection lines SSL1 to SSL3, respectively.

The first and second dummy memory cells DMC1 and DMC2 of each cell string may be coupled between the source selection transistors SST1 to SST3 and normal memory cells NMC1 to NMCp, and gates thereof may be coupled to the first and second dummy word lines DWL1 and DWL2.

The first to n-th normal memory cells NMC1 to NMCn of each cell string may be coupled between the first and second dummy memory cells DMC1 and DMC2 and the third and fourth dummy memory cells DMC3 and DMC4.

The first to n-th normal memory cells NMC1 to NMCn may be divided into first to p-th normal memory cells NMC1 to NMCp and p+1-th to n-th normal memory cells NMCp+1 to NMCn. The group of the first to p-th normal memory cells NMC1 to NMCp and the group of the p+1-th to n-th normal memory cells NMCp+1 to NMCn may be coupled to each other through the pipe transistor PT. The first to p-th normal memory cells NMC1 to NMCp may be sequentially arranged in the −Z direction and be coupled between the first and second dummy memory cells DMC1 and DMC2 and the pipe transistor PT. The p+1-th to n-th normal memory cells NMCp+1 to NMCn may be sequentially arranged in the +Z direction and be coupled in series between the pipe transistor PT and the third and fourth dummy memory cells DMC3 and DMC4. Gates of the first to n-th normal memory cells NMC1 to NMCn may be coupled to the first to n-th normal word lines NWL1 to NWLn, respectively.

A gate of the pipe transistor PT of each cell string may be coupled to a pipe line PL.

The third and fourth dummy memory cells DMC3 and DMC4 of each of the cell strings may be coupled between the drain selection transistors DST1 to DST3 and the p+1-th to n-th normal memory cells NMCp+1 to NMCn, and gates thereof may be coupled to the third and fourth dummy word lines DWL3 and DWL4.

The first to third drain selection transistors DST1 to DST3 of each cell string may be coupled in series between a corresponding bit line and the third and fourth dummy memory cells DMC3 and DMC4. Drain selection transistors of cell strings located at the same height and in the same row (+X direction) may be coupled to the same drain selection line.

The memory block BLK1′ shown in FIG. 4 may have a substantially similar equivalent circuit to the memory block BLK1 shown in FIG. 3 except that the memory block BLK1′ further includes the pipe selection transistor PT in each cell string.

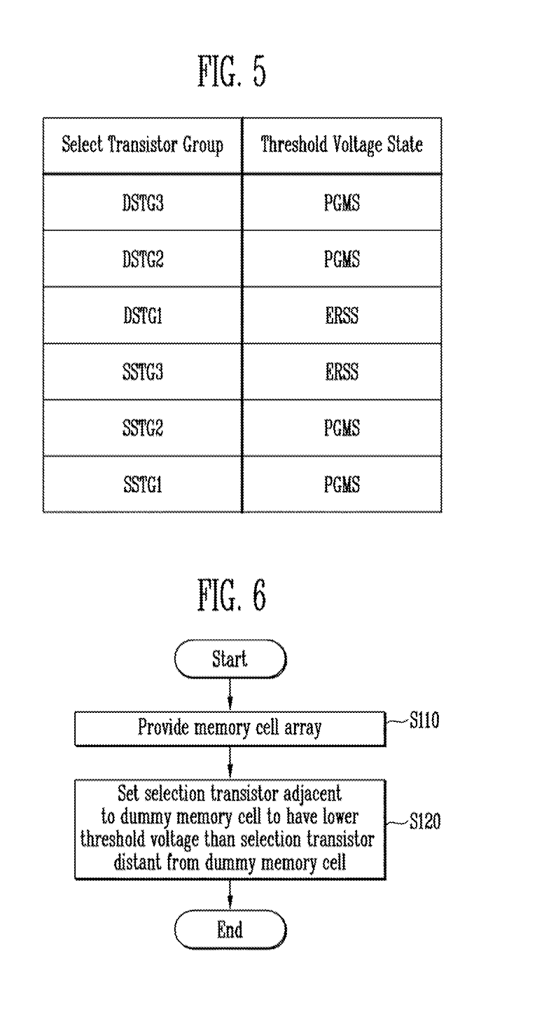

FIG. 5 is a table showing threshold voltage states of the selection transistors SST1 to SST3 and DST1 to DST3 according to an embodiment of the present invention. For example, in the table, a first source selection transistor group SSTG1 may indicate the first source selection transistors SST1 of the respective cell strings shown in FIGS. 3 and 4. A second source selection transistor group SSTG2 may indicate the second source selection transistors SST2 of the respective cell strings shown in FIGS. 3 and 4. A third source selection transistor group SSTG3 may indicate the third source selection transistors SST3 of the respective cell strings shown in FIGS. 3 and 4. A first drain selection transistor group DSTG1 may indicate the first drain selection transistors DST1 of the respective cell strings shown in FIGS. 3 and 4. A second drain selection transistor group DSTG2 may indicate the second drain selection transistors DST2 of the respective cell strings shown in FIGS. 3 and 4. A third drain selection transistor group DSTG3 may indicate the third drain selection transistors DST3 of the respective cell strings shown in FIGS. 3 and 4.

Referring to FIG. 5, source selection transistors of the first source selection transistor group SSTG1 may have higher threshold voltages than those of the third source selection transistor group SSTG3. For example, source selection transistors of the first source selection transistor group SSTG1 may have a program state PGMS. The program state PGMS may correspond to a threshold voltage higher than a ground voltage and lower than a power voltage.

Source selection transistors of the second source selection transistor group SSTG2 may have the program state PGMS.

Source selection transistors of the third source selection transistor group SSTG3 may have lower threshold voltages than those of the first and second source selection transistor groups SSTG1 and SSTG2. According to an embodiment, the source selection transistors of the third source selection transistor group SSTG3 may have lower threshold voltages than a ground voltage, for example, an erase state ERSS. In other words, a near source selection transistor group adjacent to a dummy memory cell may have lower threshold voltages than another source selection transistor group.

Drain selection transistors of the first drain selection transistor group DSTG1 may have lower threshold voltages than those of the second and third drain selection transistor groups DSTG2 and DSTG3. According to an embodiment, the drain selection transistors of the first drain selection transistor group DSTG1 may have lower threshold voltages than a ground voltage, for example, the erase state ERSS. In other words, a near drain selection transistor group adjacent to a dummy memory cell may have lower threshold voltages than another drain selection transistor group.

Drain selection transistors of the second and third drain selection transistor groups DSTG2 and DSTG3 may have higher threshold voltages than those of the first drain selection transistor group DSTG1, for example, the program state PGMS.

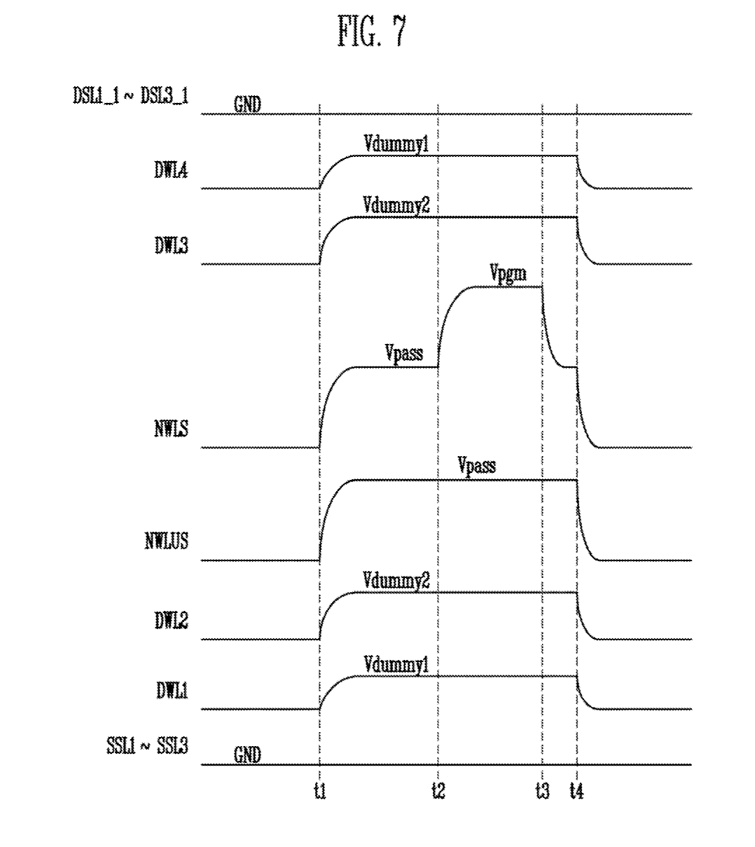

FIG. 6 is a flowchart illustrating a method of setting selection transistors to have the threshold voltage states shown in FIG. 5.

Referring to FIG. 6, the memory cell array 110 described with reference to FIGS. 1 to 4 may be provided at step S110. In other words, the first to third source selection transistors SST1 to SST3, the first and second dummy memory cells DMC1 and DMC2, the normal memory cells NMC1 to NMCn, the third and fourth dummy memory cells DMC3 and DMC4 and the first to third drain selection transistors DST1 to DST3 may be provided.

A near selection transistor adjacent to a dummy memory cell may be set to have a lower threshold voltage than a far selection transistor distant from the dummy memory cell at step S120. According to an embodiment, the near selection transistor may be set to have a lower threshold voltage than a ground voltage, for example, the erase state ERSS, and the far selection transistor may be set to have a higher threshold voltage than the ground voltage, for example, the program state PGMS.

For example, when an erase voltage Vers having a high voltage level is applied from the voltage generator 130 to a substrate (not illustrated) of the memory cell array 110, the ground voltage may be applied to the selection lines SSL1 to SSL3, DSL1_1 to DSL3_1, and DSL1_2 to DSL3_2, the dummy word lines DWL1 to DWL4 and the normal word lines NWL1 to NWLn. For example, the bit lines BL1 to BLm may be floated. The erase voltage Vers applied to the substrate may be transferred to the channel layer of the selection transistors SST1 to SST3 and DST1 to DST3 through the common source line CSL. Threshold voltages of the selection transistors SST1 to SST3 and DST1 to DST3 may be reduced by a voltage difference between the channel layer and the selection lines SSL1 to SSL3, DSL1_1 to DSL3_1 and DSL1_2 to DSL3_2. By repeating these operations, the selection transistors SST1 to SST3 and DST1 to DST3 may have relatively low threshold voltages, for example, threshold voltages in the erase state ERSS. Subsequently, the far selection transistors, for example, the second and third source selection transistors SST2 and SST3 and the first and second drain selection transistors DST1 and DST2 may be programmed to have higher threshold voltages than the ground voltage.

In another example, when the erase voltage Vers is applied from the voltage generator 130 to the substrate of the memory cell array 110, the ground voltage may be applied to the selection lines coupled to the near selection transistors, for example, the selection lines SSL3, DSL1_1 and DSL1_2 coupled to the selection transistors SST3 and DST1. On the other hand, the selection lines coupled to the other transistors including the far selection transistors, for example, the selection lines SSL1, SSL2, DSL2 and DSL3, the dummy word lines DWL1 to DWL4 and the normal word lines NWL1 to NWLn may be floated. Therefore, only the threshold voltages of the near selection transistors SST3 and DST1 may be reduced. By repeating these operations, the near selection transistors SST3 and DST1 may have relatively low threshold voltages.

In addition, the near selection transistors SST3 and DST1 according to various embodiments may be set to have threshold voltages lower than the ground voltage.

According to an embodiment, step S120 may be performed during a test operation subsequent to fabrication of the semiconductor memory device 110.

FIG. 7 illustrates voltages applied to the selection lines SSL1 to SSL3 and DSL1_1 to DSL3_1 during a program method of the semiconductor memory device 100. In FIG. 7, the selection lines SSL1 to SSL3 and DSL1_1 to DSL3_1 coupled to the selection transistors SST1 to SST3 and DST1 to DST3 have the threshold voltage states shown in FIG. 5.

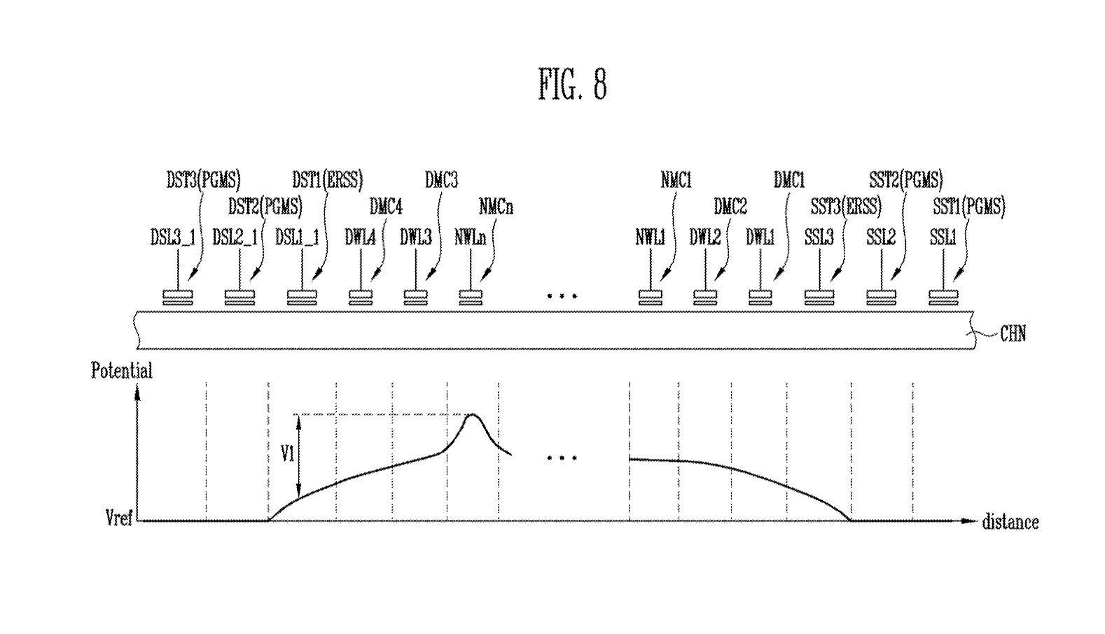

Referring to FIGS. 3, 4 and 7, during the program operation, the address decoder 120 may bias the selection lines SSL1 to SSL3 and DSL1_1 to DSL3_1 to the ground voltage GND. The selection transistors SST1 to SST3 and DST1 to DST3 that are coupled to the selection lines SSL1 to SSL3 and DSL1_1 to DSL3_1, respectively, may be turned off. Therefore, the cell strings CS11 to CS1m including the turned-off selection transistors SST1 to SST3 and DST1 to DST3, or coupled to the selection lines SSL1 to SSL3 and DSL1_1 to DSL3_1, may be electrically insulated from the bit lines BL1 to BLm and the common source line CSL, and may be floated. In other words, the cell strings CS11 to CS1m including the turned-off selection transistors SST1 to SST3 and DST1 to DST3, or coupled to the selection lines SSL1 to SSL3 and DSL1_1 to DSL3_1, may not be selected. Therefore, when a positive voltage is applied to the word lines NWL1 to NWLn and DWL1 to DWL4, the voltage of the channel layer CHN of the cell strings CS11 to CS1m may be boosted, which will be described with reference to FIG. 8.

FIG. 7 illustrates a voltage applied to unselected drain selection lines DSL1_1 to DSL3_1 among the drain selection lines DSL1_1 to DSL3_1 and DSL1_2 to DSL3_2. A power voltage may be applied to the selected drain selection lines DSL1_2 to DSL3_2 (not illustrated). The power voltage may be higher than the threshold voltages of the drain selection transistors DST1 to DST3. Therefore, the drain selection transistors DST1 to DST3 coupled to the selected drain selection lines DSL1_2 to DSL3_2 may be turned on. The cell strings CS21 to CS2m including the turned-on drain selection transistors DST1 to DST3, or coupled to the selected drain selection lines DSL1_2 to DSL3_2 may be electrically coupled to the bit lines BL1 to BLm. In other words, the cell strings CS21 to CS2m including the turned-on drain selection transistors DST1 to DST3, or coupled to the selected drain selection lines DSL1_2 to DSL3_2 may be selected.

Referring back to FIG. 7, at a first time point t1, the address decoder 120 may bias the first and fourth dummy word lines DWL1 and DWL4 to a first dummy word line voltage Vdummy1 and bias the second and third dummy word lines DWL2 and DWL3 to a second dummy word line voltage Vdummy2.

The first dummy word line voltage Vdummy1 may be lower than the second dummy word line voltage Vdummy2. In other words, the voltage Vdummy1 applied to the dummy memory cells DMC1 and DMC4 relatively closer to the selection transistors SST1 to SST3 and DST1 to DST3 may be lower than the voltage Vdummy2 applied to the dummy memory cells DMC2 and DMC3 relatively farther from the source selection transistors SST1 to SST3 and DST1 to DST3.

Concurrently, the address decoder 120 may bias a selected normal word line NWLS and unselected normal word lines NWLUS among the normal word lines NWL1 to NWLn to a pass voltage Vpass. The pass voltage Vpass may be higher than the dummy word line voltages Vdummy1 and Vdummy2.

Subsequently, at a second time point t2, the address decoder 120 may maintain the unselected normal word line NWLUS to the pass voltage, and bias the selected normal word lines NWLS to a program voltage Vpgm having a high voltage level.

As a result, the voltage of the channel layer CHN may be lowered from the middle-of-string transistor to the end-of-string transistor in each of the cell strings CS11 to CS1m, for example, the normal memory cells NMC1 to NMCn, the dummy memory cells DMC1 to DMC4 and the selection transistors SST1 to SST3 and DST1 to DST3, in order, which will be described in detail with reference to FIG. 8.

At a third time point t3, the selected normal word line NWLS may be discharged from the program voltage Vpgm to the pass voltage Vpass. At a fourth time point t4, the dummy word lines DWL1 to DWL4 and the normal word lines NWL1 to NWLn may be discharged from the pass voltage Vpass to the ground voltage GND and the program operation may be completed.

FIG. 8 is Illustrates potential distribution of the channel layer CHN of one of the cell strings CS11 to CS1m during the program operation shown in FIG. 7. FIG. 8 shows the cell strings including the selection transistors SST1 to SST3 and DST1 to DST3 having the threshold voltage states shown in FIG. 5.

Referring to FIGS. 3, 4, 7 and 8, the voltage of the channel layer CHN of the far selection transistor may be maintained at a reference voltage Vref, and the channel layer CHN of the near selection transistor may have a higher voltage than the reference voltage Vref.

The channel layer CHN may have a voltage applied to the corresponding selection transistor or a memory cell minus a threshold voltage of the corresponding selection transistor or the memory cell. The same voltage, i.e., the ground voltage GND may be applied to the selection transistors SST1 to SST3 and DST1 to DST3 through the selection lines SSL1 to SSL3 and DSL1_1 to DSL3_1, respectively. However, since the selection transistors SST1 to SST3 and DST1 to DST3 have various threshold voltages according to distance from the dummy memory cell, the potential of the channel layer CHN of each of the selection transistors SST1 to SST3 and DST1 to DST3 may vary according to the distance from the corresponding dummy memory cell.

The first and second source selection transistors SST1 and SST2 or the far source selection transistors may have the program state PGMS. When the ground voltage GND is applied through the first and second source selection lines SSL1 and SSL2, the channel layer CHN of the first and second source selection transistors SST1 and SST2 may have the ground voltage GND minus the threshold voltage corresponding to the program state PGMS, for example, the reference voltage Vref.

The third source selection transistor SST3 or the near source selection transistors may have the erase state ERSS. When the ground voltage GND is applied through the third source selection line SSL3, the channel layer CHN of the third source selection transistor SST3 may have the ground voltage GND minus the threshold voltage corresponding to the erase state ERSS, for example, a voltage higher than the reference voltage Vref.

The second and third drain selection transistors DST2 and DST3 or the far drain selection transistors may have the program state PGMS. The first and fourth drain selection transistors DST1 and DST4 or the near drain selection transistors may have the erase state ERSS. The ground voltage GND may also be applied to the first to third drain selection transistors DST1 to DST3. The channel layer CHN of the first drain selection transistor DST may have the ground voltage GND minus the threshold voltage corresponding to the erase state ERSS, for example, a voltage higher than the reference voltage Vref. The channel layer CHN of the second and third drain selection transistors DST2 and DST3 may have the ground voltage GND minus the threshold voltage corresponding to the program state PGMS, for example, the reference voltage Vref.

As disclosed above, the voltage Vdummy1 applied to the dummy memory cells DMC1 and DMC4 relatively closer to the selection transistors SST1 to SST3 and DST1 to DST3 may be lower than the voltage Vdummy2 applied to the dummy memory cells DMC2 and DMC3 relatively farther from the source selection transistors SST1 to SST3 and DST1 to DST3. Accordingly, the first dummy word line voltage Vdummy1 applied to the first and fourth dummy word lines DWL1 and DWL4 may be lower than the second dummy word line voltage Vdummy2 applied to the second and third dummy word lines DWL2 and DWL3.

Since the pass voltage Vpass having a high voltage level or the program voltage Vpgm higher than the pass voltage Vpass is applied to the normal word lines NWL1 to NWLn, the potential of the channel layer CHN of the normal memory cells NMC1 to NMCn may be higher than that of the dummy memory cells DMC1 to DMC4. Since the program voltage Vpgm is applied to a selected normal memory cell NMCn through a selected normal word line NWLn, the channel layer CHN may have the highest potential.

As described above, when the near selection transistors, for example, the selection transistors SST3 and DST1 have the erase state ERSS, and the far selection transistors, for example, the selection transistors SST1, SST2, DST2 and DST3 have the program state PGMS as described above with reference to FIG. 5, even if the ground voltage GND is commonly applied to the selection lines SSL1 to SSL3 and DSL1_1 to DSL3_1 during the program operation described above with reference to FIG. 7, the potential of the channel layer CHN of the cell string may be gradually lowered from the middle-of-string transistor or the selected normal memory cell NMCn to the end-of-string transistors or the selection transistors. In other words, the voltage gradient or the electrical intensity formed at the far selection transistors or the end-of-string transistors in the channel layer CHN of the cell string may be reduced during the program operation. Therefore, current leakage into the bit line or the common source line CSL through the selection transistors may be reduced during the program operation.

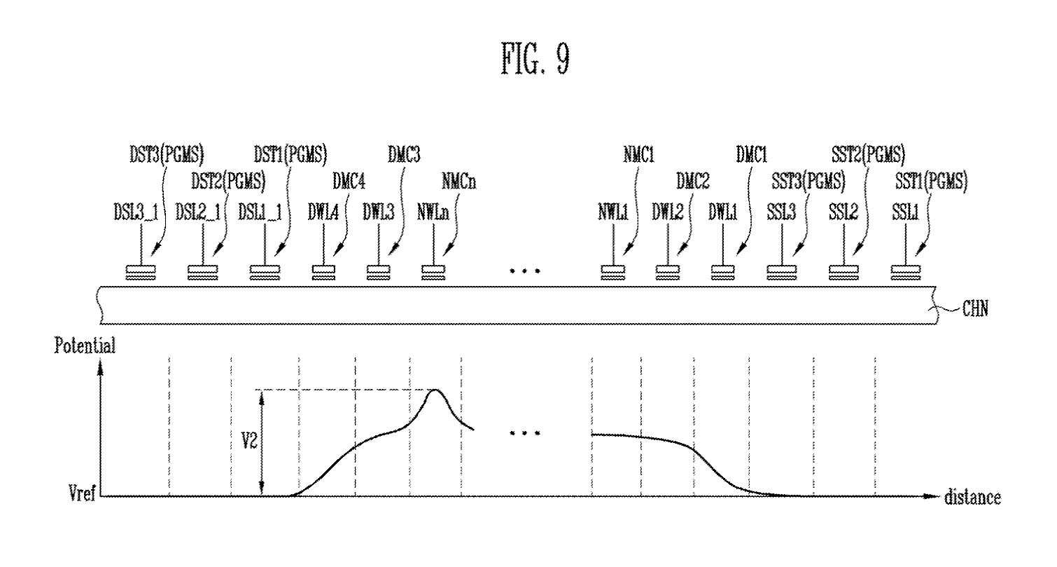

FIG. 9 is a view illustrating the potential distribution of the channel layer CHN when the near selection transistors SST3 and DST1 adjacent to the dummy memory cell have the program state PGMS.

Referring to FIG. 9, when the near selection transistors or the first drain selection transistor DST1 and the third source selection transistor SST3 may have the program state PGMS in the same manner as the far selection transistors SST1, SST2, DST2 and DST3, and the ground voltage GND is applied to the selection lines SSL1 to SSL3 and DSL1_1 to DSL3_1 during the program operation, the channel layer CHN of the first drain selection transistor DST1 and the third source selection transistor SST3 may maintain the reference voltage Vref in the same manner as the selection transistors SST1, SST2, DST2 and DST3. As a result, the potential of the channel layer CHN of the first drain selection transistor DST1 and the third source selection transistor SST3 may be lowered more than shown in FIG. 8.

Therefore, the voltage difference between the channel layer CHN of the normal memory cells NMC1 to NMC1n and the channel layer CHN of the first drain selection transistor DST1, for example, the voltage difference V2 between the channel layer CHN of the selected normal memory cell NMCn and the channel layer CHN of the first drain selection transistor DST1, may be increased more than the voltage difference V1 shown in FIG. 8. As a result, the potential of the channel layer CHN of the cell string may drastically decrease from the selected normal memory cell NMCn to the drain selection transistors DST1 to DST3. Therefore, a strong electrical field may be formed to cause a large amount of current to leak through the drain selection transistors DST1 to DST3. As a result, the channel layer CHN of the cell string may not be smoothly boosted.

For the same reason, a large amount of current may leak through the source selection transistors SST1 to SST3 and the channel layer CHN of the cell string may not be smoothly boosted.

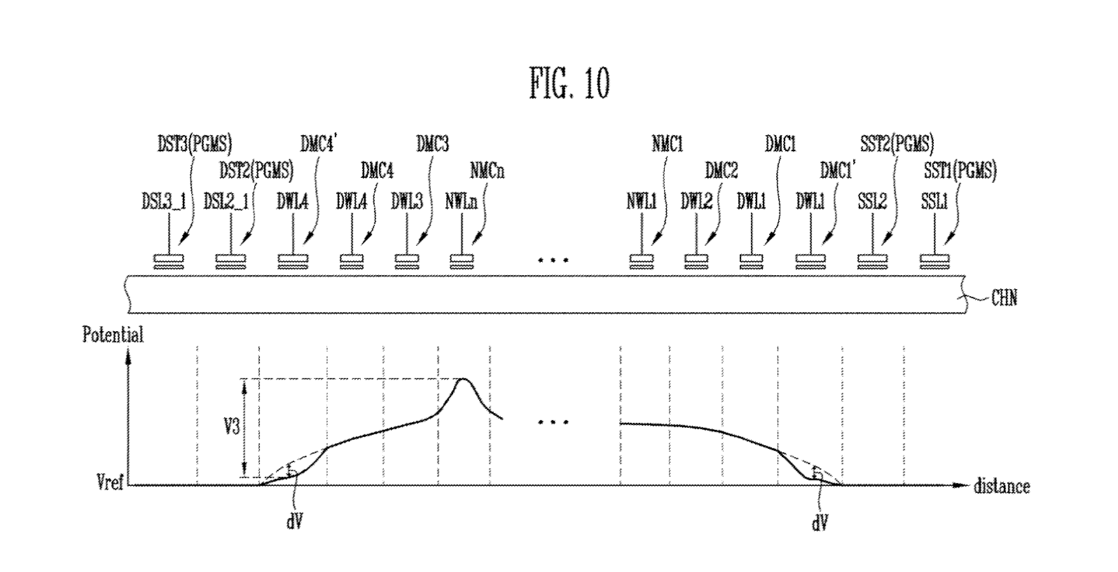

FIG. 10 is a view illustrating the potential distribution of the channel layer CHN when the near selection transistor, or the first drain selection transistor DST1 and the third source selection transistor SST3 shown in FIG. 8 are replaced by dummy memory cells DMC4′ and DMC1′, respectively.

Referring to FIGS. 3, 4, 8 and 10, the first drain selection transistor DST1 shown in FIGS. 3, 4, and 8 may be replaced by the dummy memory cell DMC4′, and the third source selection transistor SST3 shown in FIGS. 3, 4, and 8 may be replaced by the dummy memory cell DMC1′. The dummy memory cells DMC4′ and DMC1′ may have the program state PGMS.

The dummy memory cell DMC4′ may receive a voltage through a dummy word line DWL4′. The voltage of the dummy word line DWL4′ may be set so that the channel layer CHN of the dummy memory cell DMC4′ may have a potential lower than the potential of the fourth dummy memory cell DMC4 and higher than the potential of the second drain selection transistor DST2.

The dummy memory cell DMC1′ may receive a voltage through a dummy word line DWL1′. The voltage of the dummy word line DWL1′ may be set so that the channel layer CHN of the dummy memory cell DMC1′ may have a lower potential than that of the first dummy memory cell DMC1 and higher than that of the second source selection transistor SST2.

Voltages provided through the selection lines SSL1, SSL2, DSL2_1 and DSL3_1 and the word lines DWL1 to DWL4, DWL1′, DWL4′ and NWL1 to NWLn may have RC delay due to a resistance component and a capacitance component. Therefore, each of the voltages provided through the selection lines SSL1, SSL2, DSL2_1 and DSL3_1 and the word lines DWL1 to DWL4, DWL1′, DWL4′ and NWL1 to NWLn may reach a corresponding target voltage slowly.

It is assumed that the voltage of the dummy word line DWL4′ reaches the target voltage slower than an intended amount of time. When the voltage of the dummy word line DWL4′ has not yet reached the target voltage (indicated by solid line in FIG. 10), the potential of the channel layer CHN of the dummy memory cell DMC4′ may be lower than the intended level (indicated by dotted line in FIG. 10) by dV. As the voltage of the dummy word line DWL4′ slowly increases to the target voltage due to the RC delay, the potential level of the channel layer CHN of the dummy memory cell DMC4′ may be maintained at a lower level (indicated by solid line in FIG. 10) than the intended level (indicated by dotted line in FIG. 10) for a longer period of time. The voltage difference between the channel layer CHN of the dummy memory cell DMC4′ and the channel layer CHN of the normal memory cells NMC1 to NMCn, for example, the voltage difference V3 between the channel layer CHN of the dummy memory cell DMC4′ and the channel layer CHN of the selected normal memory cell NMCn may be greater than the voltage difference V1 in FIG. 8. As a result, the potential of the channel layer CHN of the cell string may drastically decrease from the selected normal memory cell NMCn to the dummy memory cell DMC4′. Therefore, a strong electrical field may be formed to cause a large amount of current to leak through the drain selection transistors DST2 and DST3. As a result, the channel layer CHN of the cell string may not be smoothly boosted.

For the same reason, a large amount of current may leak through the source selection transistors SST1 and SST2, and the channel layer CHN of the cell string may not be smoothly boosted.

According to an embodiment of the present invention, the near selection transistor adjacent to a dummy memory cell may have a lower threshold voltage than a ground voltage, and a ground voltage may be commonly applied to selection transistors through selection lines during a program operation. Therefore, the channel layer CHN of the near selection transistor may stably have a higher potential than the reference voltage Vref. As a result, the voltage gradient (electrical intensity) formed in the channel layer CHN of the cell string may be reduced, and reliability of the program operation of the semiconductor memory device 100 may be improved.

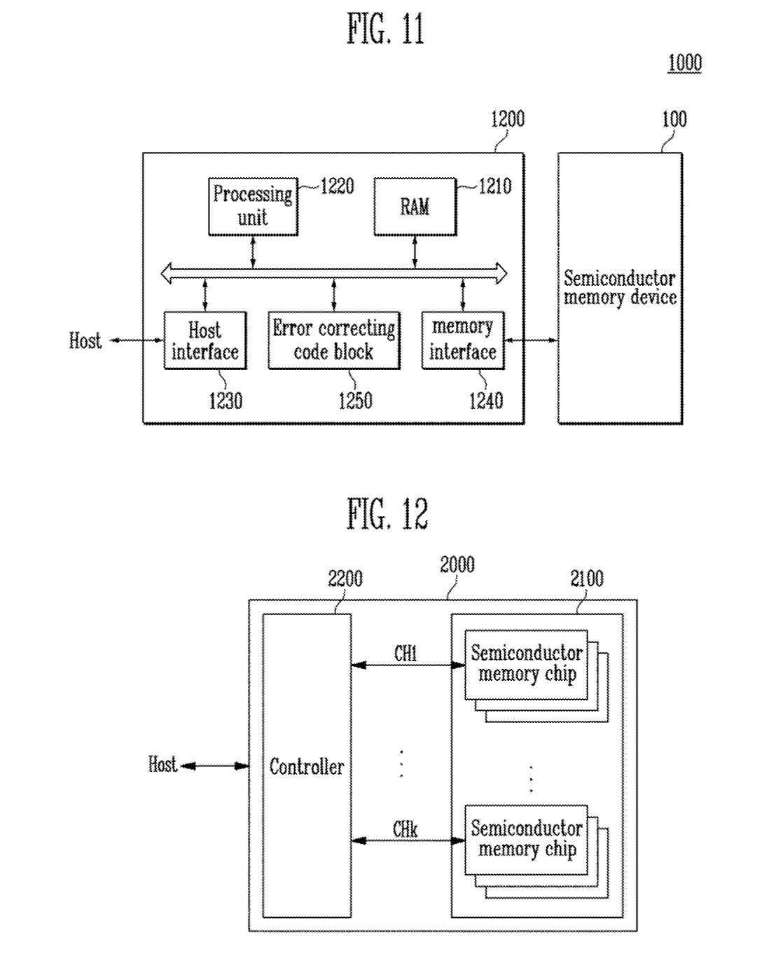

FIG. 11 is a block diagram illustrating a memory system 1000 including the semiconductor memory device 100 shown in FIG. 1.

Referring to FIG. 11, the memory system 1000 may include the semiconductor memory device 100 and a controller 1200.

The semiconductor memory device 100 may be substantially the same as the semiconductor memory device 100 described above with reference to FIGS. 1 to 8. Thus, a detailed description thereof will be omitted.

The controller 1200 may be coupled to a host and the semiconductor memory device 100. The controller 1200 may access the semiconductor memory device 100 in response to a request from the host. For example, the memory controller 1200 may control read, write, erase and background operations of the semiconductor memory device 100. The controller 1200 may provide an interface between the semiconductor memory device 100 and the host. The controller 1200 may drive firmware for controlling the semiconductor memory device 100.

The controller 1200 may include random access memory (RAM) 1210, a processing unit 1220, a host interface 1230, a memory interface 1240 and an error correcting code block 1250. The RAM 1210 may function as at least one of the operation memories of the processing unit 1220, a cache memory between the semiconductor memory device 100 and the host, and a buffer memory between the semiconductor memory device 100 and the host. The processing unit 1220 may control the general operation of the controller 1200.

The host interface 1230 may include a protocol for data exchange between the host and the controller 1200. According to an exemplary embodiment, the controller 1200 may communicate with the host through one of various interface protocols including a Universal Serial Bus (USB) protocol, a multimedia card (MMC) protocol, a peripheral component interconnection (PCI) protocol, a PCI-express (PCI-E) protocol, an Advanced Technology Attachment (ATA) protocol, a Serial-ATA protocol, a Parallel-ATA protocol, a small computer small interface (SCSI) protocol, an enhanced small disk interface (ESDI) protocol, an Integrated Drive Electronics (IDE) protocol and a private protocol.

The memory interface 1240 may include a protocol for communication with the semiconductor memory device 100. For example, the memory interface 1240 may include at least one flash interface, such as a NAND interface and a NOR interface.

The ECC block 1250 may detect an error in data from the semiconductor memory device 100 by using an error correcting code (ECC).

The controller 1200 and the semiconductor memory device 100 may be integrated into a single semiconductor device. In an exemplary embodiment, the controller 1200 and the semiconductor memory device 100 may be integrated into a single semiconductor device to form a memory card. For example, the controller 1200 and the semiconductor memory device 100 may be integrated into a single semiconductor device to form a PC card (personal computer memory card international association (PCMCIA)), a compact flash (CF) card, a smart media card (SM or SMC), a memory stick, a multimedia card (MMC, RS-MMC or MMCmicro), an SD card (SD, miniSD, microSD or SDHC), or a universal flash storage card (UFS).

The controller 1200 and the semiconductor memory device 100 may be integrated into a single semiconductor device to form a semiconductor drive (Solid State Drive (SSD)). The semiconductor drive (SSD) may include a storage device configured to store data in a semiconductor memory. When the memory system 1000 is used as the semiconductor drive (SSD), the operating speed of the host coupled to the memory system 1000 may be significantly improved.

In another example, the memory system 1000 may be used as one of various components of an electronic device, such as a computer, an ultra mobile PC (UMPC), a workstation, a net-book, personal digital assistants (PDAs), a portable computer, a web tablet, a wireless phone, a mobile phone, a smart phone, an e-book, a portable multimedia player (PMP), a portable game machine, a navigation device, a black box, a digital camera, a three-dimensional (3D) television, a digital audio recorder, a digital audio player, a digital picture recorder, a digital picture player, a digital video recorder, a digital video player, a device for transmitting/receiving information in wireless environment, one of various electronic devices for home networks, one of various electronic devices for computer networks, one of various electronic devices for telematics networks, an RFID device and/or one of various devices for computing systems, etc.

In an exemplary embodiment, the semiconductor memory device 100 or the memory system 1000 may be packaged in a variety of ways. For example, in some embodiments, the semiconductor memory device 100 or the memory system 1000 may be packaged using various methods such as a package on package (PoP), ball grid arrays (BGAs), chip scale packages (CSPs), a plastic leaded chip carrier (PLCC), a plastic dual in line package (PDIP), a die in waffle pack, a die in wafer form, a chip on board (COB), a ceramic dual in line package (CERDIP), a plastic metric quad flat pack (MQFP), a thin quad flatpack (TQFP), a small outline (SOIC), a shrink small outline package (SSOP), a thin small outline (TSOP), a thin quad flatpack (TQFP), a system in package (SIP), a multi chip package (MCP), a wafer-level fabricated package (WFP) and/or a wafer-level processed stack package (WSP), etc.

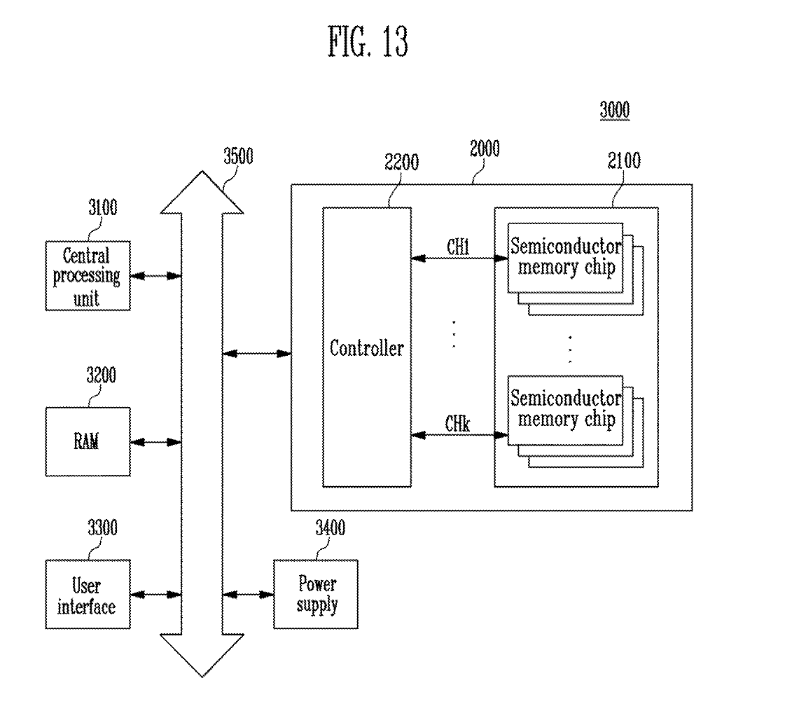

FIG. 12 is a block diagram illustrating an application example 2000 of the memory system 1000 shown in FIG. 11.

Referring to FIG. 12, a memory system 2000 may include a semiconductor memory device 2100 and a controller 2200. The semiconductor memory device 2100 may include a plurality of semiconductor memory chips. The semiconductor memory chips may be divided into a plurality of groups.

FIG. 12 illustrates the plurality of groups communicating with the controller 220 through first to k-th channels CH1 to CHk, respectively. Each of the memory chips may be configured and operated in substantially the same manner as the semiconductor memory device 100 described above with reference to FIG. 1.

Each of the groups may communicate with the controller 2200 through a single common channel. The controller 2200 may be configured in substantially the same manner as the controller 1200 described above with reference to FIG. 11 and may control the plurality of memory chips of the semiconductor memory device 2100.

FIG. 12 illustrates the plurality of semiconductor memory chips coupled to a single channel. However, the memory system 2000 may be modified so that a single semiconductor memory chip may be coupled to a single channel.

FIG. 13 is a block diagram illustrating a computing system 3000 including the memory system 2000 shown in FIG. 12.

Referring to FIG. 13, the computing system 3000 may include a central processing unit 3100, random access memory (RAM) 3200, a user interface 3300, a power supply 3400, a system bus 3500, and the memory system 2000.

The memory system 2000 may be electrically coupled to the central processing unit 3100, the RAM 3200, the user interface 3300 and the power supply 3400 through the system bus 3500. Data provided through the user interface 3300 or processed by the central processing unit 3100 may be stored in the memory system 2000.

FIG. 13 illustrates the semiconductor memory device 2100 coupled to the system bus 3500 through the controller 2200. However, the semiconductor memory device 2100 may be directly coupled to the system bus 3500. Functions of the controller 2200 may be performed by the central processing unit 3100 and the RAM 3200.

FIG. 13 illustrates the memory system 2000 described above with reference to FIG. 12. However, the memory system 2000 may be replaced by the memory system 1000 described above with reference to FIG. 10. In an exemplary embodiment, the computing system 3000 may include both memory systems 1000 and 2000 described above with reference to FIGS. 11 and 12, respectively.

According to an embodiment of the present invention, reliability of a program operation of a semiconductor memory device may be improved.

While the present invention has been described with respect to the specific embodiments, it will be apparent to those skilled in the art that various changes and modifications may be made without departing from the spirit and scope of the invention as defined in the following claims.

What is claimed is:

1. A semiconductor memory device, comprising:
a plurality of normal memory cells stacked over a substrate and coupled in series with each other;
a plurality of selection transistors coupled in series; and
one or more dummy memory cells coupled between the plurality of normal memory cells and the plurality of selection transistors,
wherein the plurality of selection transistors include first and second selection transistors, and
wherein the first selection transistor is adjacent to the dummy memory cells, and has a lower threshold voltage than the second selection transistor.

2. The semiconductor memory device of claim 1,
wherein the threshold voltage of the first selection transistor is lower than a ground voltage, and
wherein the second selection transistor has a higher threshold voltage than the ground voltage.

3. The semiconductor memory device of claim 1, wherein the threshold voltage of the first selection transistor corresponds to an erase state.

4. The semiconductor memory device of claim 1, wherein a single voltage is applied to the plurality of selection transistors during a program operation.

5. The semiconductor memory device of claim 4, wherein a dummy word line voltage lower than voltages applied to the plurality of normal memory cells is applied to the one or more dummy memory cells during the program operation, and
the single voltage applied to the plurality of selection transistors is lower than the dummy word line voltage.

6. The semiconductor memory device of claim 4, wherein the single voltage applied to the plurality of selection transistors is a ground voltage.

7. The semiconductor memory device of claim 1, wherein dummy word line voltages are applied to dummy memory cells during a program operation, and the dummy word line voltages decrease as corresponding dummy memory cell is closer to the plurality of selection transistors.

8. The semiconductor memory device of claim 7, wherein a lower voltage than the dummy word line voltages is applied to the plurality of selection transistors.

9. The semiconductor memory device of claim 1, wherein the plurality of selection transistors are coupled between a bit line and the at least one dummy memory cell.

10. The semiconductor memory device of claim 1, wherein the plurality of selection transistors are coupled between a common source line and the at least one dummy memory cell.

11. A semiconductor memory device, comprising:
a plurality of normal memory cells stacked over a substrate and coupled in series;
a plurality of selection transistors coupled in series; and
one or more dummy memory cells coupled between the plurality of normal memory cells and the plurality of selection transistors,
wherein the plurality of selection transistors includes a first selection transistor, and
wherein the first selection transistor is adjacent to the dummy memory cells, and has a lower threshold voltage than a ground voltage.

12. The semiconductor memory device of claim 11,
wherein the threshold voltage of the first selection transistor corresponds to an erase state.

13. The semiconductor memory device of claim 11, wherein the plurality of selection transistors further includes second selection transistors having higher threshold voltages than the ground voltage.

14. The semiconductor memory device of claim 13, wherein the first selection transistor is coupled to a first selection line, and
the second selection transistors are respectively coupled to second selection lines.

15. The semiconductor memory device of claim 11, wherein during a program operation, a dummy word line voltage is applied to the one or more dummy memory cells, and
a lower voltage than the dummy word line voltage is applied to the plurality of selection transistors.

16. A semiconductor memory device, comprising:
a plurality of normal memory cell groups stacked over a substrate;
one or more dummy memory cell groups formed on the plurality of normal memory cell groups; and
a plurality of selection transistor groups sequentially formed on the dummy memory cell groups,
wherein the plurality of selection transistor groups include first and second selection transistor groups, and
wherein selection transistors of the first selection transistor group are adjacent to the dummy memory cell groups, and have lower threshold voltages than selection transistors of the second selection transistor group.

17. The semiconductor memory device of claim 16,
wherein the threshold voltages of the first selection transistor group are lower than a ground voltage, and
wherein the second selection transistor group has higher threshold voltages than the ground voltage.

18. The semiconductor memory device of claim 16, wherein the threshold voltages of the first selection transistor group correspond to an erase state.

19. The semiconductor memory device of claim 16,
wherein the selection transistors of each of the plurality of selection transistor groups are coupled to a plurality of drain selection lines extending in a row direction, and
wherein the plurality of selection transistor groups are arranged between a plurality of bit lines extending in a column direction and the dummy memory cell groups.

20. The semiconductor memory device of claim 16,
wherein the selection transistors of each of the plurality of selection transistor groups are commonly coupled to a single source selection line, and
wherein the plurality of selection transistor groups are arranged between a common source line and the dummy memory cell groups.
